(19) United States
(12) Patent Application Publication
(10) Pub. No.: US 2012/0273904 A1
(43) Pub. Date: Nov. 1, 2012

(54) MINERAL ELECTRET-BASED ELECTROMECHANICAL DEVICE AND METHOD FOR MANUFACTURING SAME

(75) Inventors: Emmanuel Defay, Voreppe (FR); Sebastien Boisseau, Grenoble (FR); Ghislain Despesse, Saint Egreve (FR)

(73) Assignee: Commissariat a l'energie atomique et aux energies alternatives, Paris (FR)

(21) Appl. No.: 13/518,056

(22) PCT Filed: Dec. 21, 2010
(86) PCT No.: PCT/EP2010/070411

§ 371 Date: Jun. 21, 2012

(30) Foreign Application Priority Data
Dec. 23, 2009 (FR) 09 59514

(51) Int. Cl. H01L 29/84; H01L 21/02

(52) U.S. Cl. 257/416; 438/50; 257/E29.324; 257/E21.002

(57) ABSTRACT

This device includes a dielectric stack including at least one electret layer (2E), and two electrodes (16, 20) on two opposite faces (18, 22) of the stack. The electret is mineral. The device notably applies to the field of telecommunications.

### TECHNICAL FIELD

The present invention concerns an electromechanical device (MEMS or NEMS) such as, for example, an electromechanical actuator or a sensor, or again an acoustic resonator, notably one with a high quality factor, together with a method of manufacturing this device.

It notably applies to the field of telecommunications.

### STATE OF THE PRIOR ART

In the telecommunications field it is necessary to have very precise time bases, with frequencies ranging from a few hundred megahertz to a few gigahertz.

To accomplish this, use is most often made of an oscillator the oscillation frequency of which is regulated by a piezoelectric resonator, a resonator where the electromechanical resonance frequency has a sufficiently high impedance variation to impose the oscillator's frequency.

It is recalled that the figure of merit of a resonator, for an application to oscillators, is the product of the quality factor Q and the resonance frequency F.

The desired value of the product Q×F is of the order of 10¹⁴ Hz for the most precise frequency sources of roaming systems.

The resonators most commonly used include bulk elements made of quartz.

They have the disadvantage that they resonate at frequencies F of a few megahertz since they are thick: their thickness is of the order of 100 μm at minimum; but they have a very high quality factor, of the order of 100000, producing a very satisfactory stability of the oscillators at a few megahertz.

In order to have higher frequencies the quartz's resonance frequency may be made higher; but the quality factor is then reduced so that the product Q×F remains almost constant, of the order of 10¹² Hz.

In addition, increasing the frequency requires energy, which is not desirable in roaming systems.

Finally, a quartz-based resonator replacement solution is highly desirable, particularly for integrated technology on silicon.

To avoid increasing the frequency, and to work in this latter technology, a resonator may be used which is smaller than a quartz-based structure, and which has a resonance frequency already of the order of 1 GHz, namely an FBAR-type structure (Film Bulk Acoustic Resonator), including a thin piezoelectric layer which is deposited on a substrate, and often has an aluminium nitride base.

The quality factor is then only of the order of 1000, as is for example described in the article by R. C. Ruby et al., Thin film bulk acoustic wave resonators for wireless applications, IEEE Ultrasound. Symp. pp. 813-821, 2001). But the maximum product Q×F is of the order of 10¹² Hz. However, this solution requires the use of new materials in the integrated technology on silicon, namely materials such as AlN, ZnO, Mo and Pt, for example.

Another possibility is to use an HBAR-type resonator (High-tone Bulk Acoustic Resonator), including an acoustic resonant cavity, in other words a substrate of acoustic quality, on which are deposited, in succession, an electrode, a thin piezoelectric layer and another electrode.

In such a resonator the electric excitation of the thin piezoelectric layer by means of the electrodes enables an entire series of harmonics to be generated, due to the presence of the acoustic cavity.

On the subject of HBAR-type resonators, reference may be made to the article by M. Pijolat et al., Large Q×f product for HBAR using Smart Cut™ transfer of LiNbO₃ thin layers onto LiNbO₃ substrate, 2008 IEEE International Ultrasonics Symposium, 2008: 201-4 IEEE, Piscataway, N.J., USA, Conference Paper.

Use of an HBAR-type resonator has the advantages of both the previous solutions (quartz-based resonator and FBAR-type resonator): the quality factor is very high and the resonance frequencies of the different harmonics persist as high as frequencies of the order of several gigahertz.

In addition, the use of this type of resonator enables Q×F products of the order of 10¹⁴ Hz to be attained (notably if the thin layer is made of AlN and the substrate of sapphire). However, the presence of very many harmonics, with frequencies very close to one another, is often a source of instability of the oscillator.

It should be noted that the quality factor of an HBAR-type resonator results principally from the presence of the substrate which constitutes the acoustic cavity, and must be made from a monocrystalline material with very low acoustic losses, such as sapphire. The existence of resonances at frequencies of the order of 1 GHz is, for its part, due to the presence of the thin piezoelectric layer.

Since the latter is deposited on the substrate it does not have an intrinsically very high quality factor.

But since the acoustic energy is principally concentrated in the cavity, the low quality factor of the thin layer has little influence on the resonator's effective quality factor.

### ACCOUNT OF THE INVENTION

The object of the present invention is an electromechanical device, particularly an acoustic resonator, which provides a solution to the above disadvantages.

The invention concerns an electromechanical device including:
a dielectric stack having two opposite faces, and including at least one electret layer, and
two electrodes supported respectively by the opposite faces of the stack,
   characterised in that the electret is a mineral electret.

The present invention is therefore limited to mineral electrets (which can be amorphous or crystalline): polymer electrets are excluded from it.

Hitherto, non-polymer electrets had never been used to manufacture resonators.

Mineral electrets, such as SiO₂, SiN, Al₂O₃ and SrTiO₃ for example, have the advantage that they are much more rigid than polymer electrets.

Document US 2007/063793 describes acoustic resonators which include electrets made from polymer materials. But such materials cannot be suitable for the manufacture of resonators intended to operate at frequencies of the order of several gigahertz: they are too viscous. Conversely, electrets with a mineral material base are very suitable for such frequencies.

It is stipulated that the dielectric stack forming part of the device which is the object of the invention can comprise a single layer, which is then the electret layer, or several dielectric layers, at least one of which is the electret layer.

It should be mentioned that a dielectric material is an electrostrictive material; however, dielectric materials are not necessarily piezoelectric.

In the invention the electret layer can include permanent electric charges, forming an electromechanical coupling.

It is stipulated that when the dielectric layer includes, in addition to the electret layer, one or more non-piezoelectric layers, the use of charges in the electret layer enables an electromechanical coupling to be created which can be used to form, equally, an acoustic resonator or an electromechanical actuator, and even an electromechanical sensor.

The dielectric stack outside the electret may or may not be piezoelectric. For its part, the electret may or may not be piezoelectric.

The thickness of the electret layer may be chosen to be from a few nanometres to a few tens of micrometres; it is preferably less than or equal to approximately 1 μm.

The electromechanical device forming the object of the invention may also include a substrate on one face of which the stack and the electrodes are located.

It is stipulated that, regardless of the thickness of the electret layer, the electromechanical device may include a substrate.

According to a particular embodiment of the invention the substrate has a cavity, or hole, which emerges at least in the face of the substrate on which one of the two electrodes lies, where the said electrode is at least partly above the cavity.

There may of course be an intermediate layer between the substrate and the electrode, notably to improve adhesion, or to insulate the electrode.

It is stipulated that the use of a substrate with a hole (whether or not a blind hole) enables the stack, having the electrodes, to move perpendicularly to the planes of the layers.

This embodiment is particularly advantageous for the production of structures of the electromechanical actuator type or electromechanical sensor type, or again of the acoustic resonator type, such as, for example an FBAR (Film Bulk Acoustic Resonator).

When the substrate of the device according to the invention has no holes, the corresponding device is particularly advantageous for the production of acoustic resonators, and notably resonators of the HEAR type (High overtone Bulk Acoustic Resonator).

According to another particular embodiment of the invention, the electromechanical device also includes an acoustic Bragg grating having two opposite faces, one of which lies on a face of the substrate, and the other of which supports one of the two electrodes.

It is stipulated that the use of a substrate associated with a Bragg grating under the stack and the electrodes notably allows the production of an acoustic resonator.

In the invention the mineral electret layer may be crystalline or, conversely, amorphous.

The present invention also concerns a method of manufacture of an electromechanical device, including:
the formation of a dielectric stack having two opposite faces, where the said stack includes at least one layer made of dielectric material,
permanent electrical charging of the said layer made of dielectric material to form an electret layer, and
the formation of first and second electrodes respectively on these two opposite faces,
   characterised in that the dielectric material is a mineral dielectric material.

In this method the thickness of the electret layer may be chosen to be from a few nanometres to a few tens of micrometres; it is preferably less than or equal to approximately 1 μm.

The dielectric stack and the electrodes can be produced above a substrate, either directly or indirectly (for example above an intermediate layer which may act as an etch-stop layer).

According to a first particular embodiment of this method, starting with a substrate having a sacrificial layer and the first electrode which is lying above the sacrificial layer,
the dielectric stack including at least the layer made of dielectric material is formed on the first electrode,
permanent electrical charging of the layer made of dielectric material is accomplished,
the second electrode is formed on the said stack, and
the sacrificial layer is at least partly eliminated, to form a hole, or cavity, under the first electrode.

According to a second particular embodiment:
at one face of the substrate, an etch-stop layer is possibly formed, then the first electrode is formed, which lies on this face of the substrate, above the stop layer when present,
the dielectric stack including at least the layer made of dielectric material is formed on the first electrode,
permanent electrical charging of the layer made of dielectric material is accomplished,
the second electrode is formed on the said stack, and
the substrate is etched from the face opposite the first face as far as the stop layer when present, so as to make a hole, or cavity, under the first electrode.

According to a third particular embodiment:
an acoustic Bragg grating is formed on a substrate, at one face of this substrate,
the first electrode and the dielectric stack including at least the layer made of dielectric material are then formed on this grating,
permanent electrical charging of the layer made of dielectric material is accomplished, and
the second electrode is formed on the said stack.

In the method permanent electrical charging can be accomplished by a method chosen from among ion implantation and/or electronic implantation and/or Corona discharge and/or the wet electrode method.

In this wet electrode method the electrical charging is accomplished by contact with a liquid, before the formation of the second electrode.

We shall return to this method at the end of the present description.

It is stipulated that the order of the steps of the method forming the object of the invention can be modified.

In particular, the electret may be charged after formation of the second electrode.

### BRIEF DESCRIPTION OF THE DRAWINGS

The present invention will be better understood on reading the description of example embodiments given below, purely as an indication and in no sense restrictively, making reference to the appended illustrations in which:

FIGS. 1 to 3 illustrate schematically a first particular embodiment of the method forming the object of the invention,

FIGS. 4 to 7A illustrate schematically a second particular embodiment of the method forming the object of the invention,

FIG. 7B illustrates schematically a variant embodiment of the method illustrated by FIG. 7A,

FIGS. 8 to 10 illustrate schematically a third particular embodiment of the method forming the object of the invention,

FIGS. 11 to 13 illustrate schematically a fourth particular embodiment of the method forming the object of the invention,

FIGS. 14 to 17 illustrate schematically a fifth particular embodiment of the method forming the object of the invention, and

FIGS. 18, 19 and 20 illustrate schematically the principle of the wet electrode method, which can be used in the invention.

### DETAILED ACCOUNT OF PARTICULAR EMBODIMENTS

On the subject of the “Smart Cut™” technique, reference will be made, for example, to the article by M. Bruel, Application of hydrogen ion beams to Silicon On Insulator material technology, Nuclear Instruments and Methods in Physics Research, Section B Beam Interactions with Materials and Atoms, February 1996, B 108(3): 313-19, or to patent FR 2 681 472.

This method is also described, for example, in the article by B. Aspar et al., “Silicon Wafer Bonding Technology for VLSI and MEMS applications”, edited by S. S. Iyer and A. J. Auberton-Hervé, 2002, INSPEC, London, Chapter 3, pages 35-52.

Use of a Corona discharge is also mentioned in what follows.

On the subject of Corona discharges, reference will be made, for example, to the article by J. A. Giacometti et al., Corona Charging of Polymers, IEEE Transactions on Electrical Insulation, vol. 27, n^{o} 5, October 1992.

According to one aspect of the invention, a non-piezoelectric dielectric material, with very low acoustic losses, for example sapphire or STO (SrTiO₃), is used, and permanent electrical charging of this material is accomplished, in order to transform it into an electret.

As was seen, this charging can be accomplished by ion implantation, by electronic implantation, or by the technique known by the name Corona discharge.

When the material permanently charged in this manner is positioned between two electrodes, an electro-acoustic resonance appears when an electric field is imposed on the electrodes.

In other words, the material becomes piezoelectric induced.

Various examples of the method forming the object of the invention are described below, to obtain a resonator with very low acoustic losses.

The first example concerns the manufacture of a bulk resonator of sapphire.

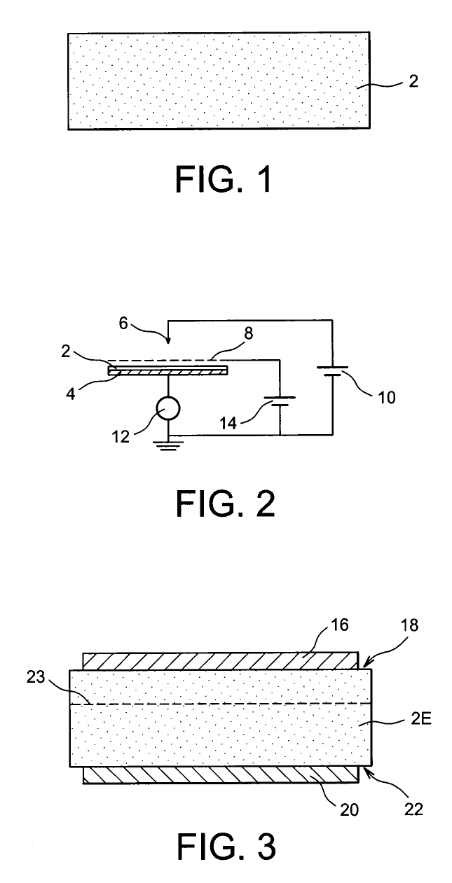

In this example a thick layer 2 of sapphire is used, which is at least 100 μm thick, for example 500 μm thick (FIG. 1).

Permanent electrical charging of layer 2 is then accomplished by ion implantation, by electronic implantation or by Corona discharge, to transform it into an electret layer 2E.

FIG. 2 illustrates this step, using Corona discharge in the example.

To implement this technique layer 2 lies on an electrode which is grounded.

A tip-shaped electrode 6 is positioned above layer 2.

A grid 8 is positioned between electrode 6 and layer 2.

Discharge is obtained by applying a high positive potential, for example 10 kV, to electrode 6, by means of an appropriate voltage source 10.

As can be seen in FIG. 2, the current of the discharge is measured by an ammeter 12 and controlled by adjusting the potential of grid 8 by means of an appropriate voltage source 14.

An electrode 16 is then formed on one face 18 of layer 2E, and another electrode 20 on opposite face 22 of layer 2E. To form these electrodes a metal, for example aluminium, may be deposited on these faces 18 and 22 (FIG. 3).

In FIG. 3, reference 23 designates the charged zone (having non-zero thickness).

The second example concerns the manufacture of a monocrystalline, thin layer resonator using a non-piezoelectric, dielectric material.

This resonator does not require the application of a direct voltage between its electrodes when in operation.

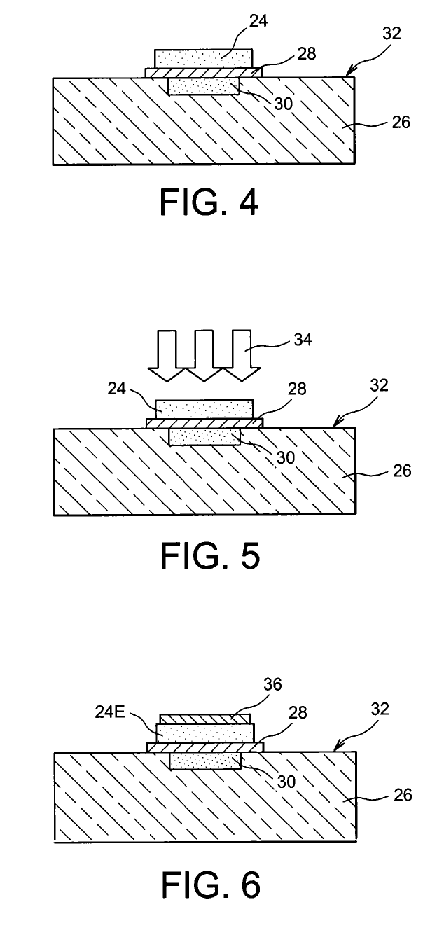

In this example a thin monocrystalline sapphire layer 24 is used (FIG. 4). This layer is for example 1 μm thick.

In addition, a substrate 26, for example made of silicon, is formed, having an electrode 28 and a sacrificial layer 30 at one face 32 of the substrate.

Electrode 28 lies on this face, above sacrificial layer 30.

Electrode 28 is, for example, obtained by vapour deposition of a metal, for example aluminium, above layer 30.

Thin layer 24 is then transferred to electrode 28. To do so, the “Smart Cut™” technique may be used, to which we shall return at the end of the present description.

As a variant, a thick layer of monocrystalline sapphire is used; it is bonded to electrode 28, for example by molecular bonding; the thick layer is then thinned, for example by grinding, until the desired thickness for the thin layer is obtained.

Permanent electrical charging of layer 24 is then accomplished by ion or electric implantation, or by Corona discharge (FIG. 5).

The electric charges sent into layer 24 bear reference 34 in FIG. 5.

Another electrode 36 is then formed on electret layer 24E (FIG. 6) which results from the charging of layer 24.

To accomplish this, a layer of aluminium, for example, is deposited on this layer 24E; the aluminium layer is then structured by photolithography and etching.

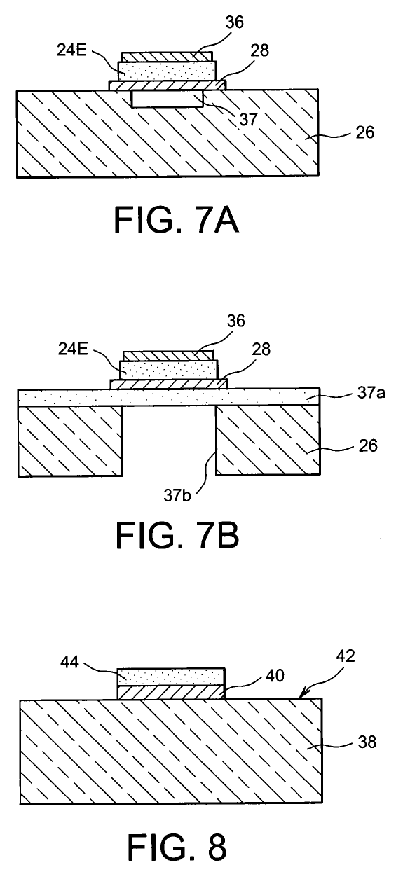

After this, sacrificial layer 30 is eliminated, for example by chemical etching (FIG. 7A), which leads to the formation of a cavity 37 under the resonator.

The formed resonator is thus “released”: it is then surrounded with air.

Release of the membrane constituted by the resonator can also be obtained by etching of silicon substrate 26, through the rear face of the latter. This is then a deep etching in this substrate.

An intermediate layer can then be added between lower electrode 28 and substrate 26. This layer may be used as an etch-stop layer.

This is illustrated schematically by FIG. 7B, where etch-stop layer 37a can be seen, formed between substrate 26 and electrode 28, and a through hole 37b, formed through the substrate, under etch-stop layer 37a.

It is stipulated that the etch-stop layer is not essential; use of it depends on the etching method and the materials used.

In a third example a resonator having an HBAR-type structure is manufactured. As above, a thin layer of sapphire can be used. And if the substrate is itself made of sapphire an “all-sapphire” structure is obtained.

Substrate 38 has an electrode 40, made for example of aluminium, which lies on a face 42 of the substrate (FIG. 8).

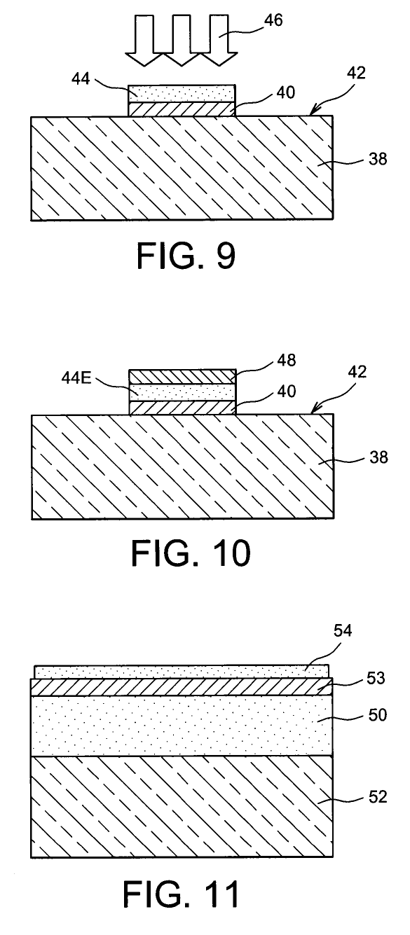

As above, thin sapphire layer 44 is formed on electrode 40; after this (FIG. 9) permanent electrical charging of layer 44 is accomplished (arrows 46 symbolise this charging), to transform layer 44 into electret layer 44E; and another electrode 48 is formed on layer 44E (FIG. 10).

For example, if layer 44 is 1 μm thick and electrodes 40 and 48 are 100 nm thick respectively, a substrate 38 which is 50 μm thick can be used.

In a fourth example, a resonator including a thin STO (SrTiO₃) layer is manufactured on an acoustic Bragg grating.

In this case, this grating is used to confine the acoustic energy of the resonator which is constituted by the SrTiO₃ layer and by two electrodes.

On the subject of such a grating, reference will be made, for example, to the article by K. M. Lakin et al., Development of miniature filters for wireless applications, IEEE Trans. Microwave Theory Tech., vol. 43, n^{o} 12, pp. 2933-2939, 1995.

Acoustic Bragg grating 50 (FIG. 11), made for example of W/SiO₂/W/SiO₂, is formed on a substrate 52 made, for example, of silicon. After this an electrode 53 is formed, for example made of platinum, on acoustic Bragg grating 50.

We shall return to such a grating at the end of the present description.

After this, thin layer of STO 54 is formed on electrode 53. As above, layer 54 may be transferred or made thinner.

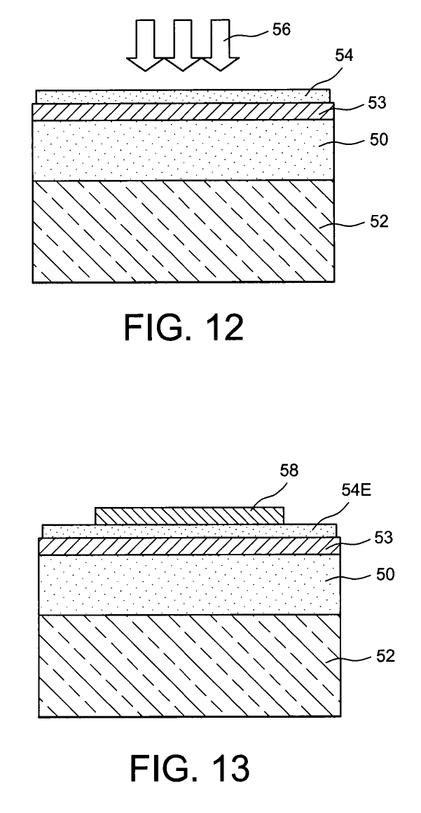

Permanent electrical charging of layer 54 is then accomplished to transform it into an electret layer, as shown in FIG. 12, where arrows 56 symbolise this charging.

After this, an electrode 58 is formed, for example made of platinum, on electret layer 54E, by deposition followed by structuring (FIG. 13).

The method forming the object of the invention can also be implemented with dielectric, non-piezoelectric materials of lesser acoustic quality than sapphire or STO, for example materials deposited by all possible techniques (in particular sputtering, evaporation, CVD, MOCVD, ALD, MBE), and in particular the following materials: SiO₂, SiₓN_{y}, Al₂O₃, HfO₂, Y₂O₃, ZrO₂, TiO₂, deposited SrTiO₃, (Ba, Sr)TiO₃.

Such a method is particularly advantageous for integrated technology on silicon.

Indeed, this is a method which can be fully compatible with CMOS structures, and which uses only materials which are well known in the CMOS field.

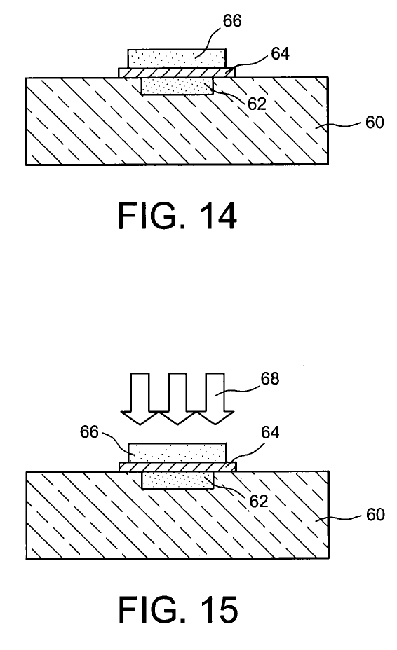

This is illustrated by an example, making reference to FIGS. 14 to 17.

This example uses amorphous SiO₂, which is deposited by CVD.

The method used in this example is particularly advantageous in the case of microelectronic integration.

Indeed, as will be seen, it requires only materials which are fully compatible with CMOS technology: Si, SiO₂ and Al or Cu.

The steps of this example correspond to the steps of the second example given above, by making reference to FIGS. 4 to 7 (the latter correspond respectively to FIGS. 14 to 17), with the difference that the thin sapphire layer is replaced by a thin layer of SiO₂.

This layer is charged by ion or electronic implantation, or by Corona discharge.

The upper electrode is then deposited and structured.

More specifically, a structure is formed including a substrate 60, made for example of silicon, a sacrificial layer 62, an electrode 64, made for example of aluminium or copper, on substrate 60, above the sacrificial layer; and thin SiO₂ layer 66 is formed on electrode 64 (FIG. 14).

Layer 66 is then charged electrically in permanent fashion, to form the electret layer (FIG. 15).

The charging is symbolised by arrows 68.

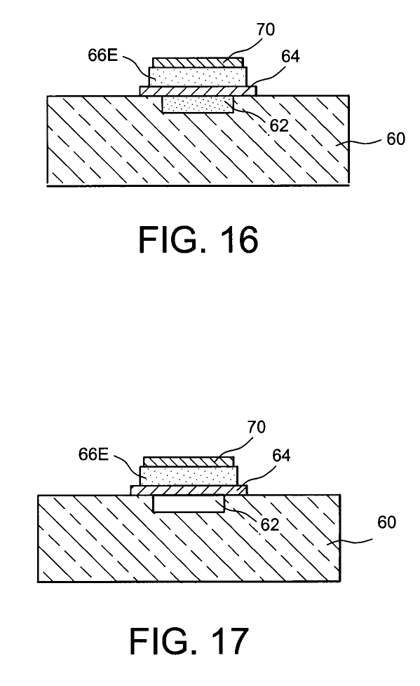

After this, an electrode 70 is formed, made for example of aluminium or copper, on electret layer 66E (FIG. 16); sacrificial layer 62 is then eliminated (resulting in the formation of a cavity 72), to release the resonator which is thus surrounded with air (FIG. 17).

In the foregoing, a variant of the second example has thus been described. But it is also possible to implement comparable variants for the third and fourth examples.

And, in the first example, the thick sapphire layer could also be replaced by a thick layer of an amorphous, non-piezoelectric, dielectric material, for example a thick layer of amorphous SiO₂.

We now return below to Corona discharges.

Corona discharges are generally used in photocopiers, for the production of ozone, or to improve the wettability of certain materials.

In the case of the present invention, its aim is to inject charges into a dielectric material which is capable of retaining them for a long period (typically several years): this is an electret. This results in the appearance of a surface potential and the creation of an electric field within the material. This is an electric dipole, in the same way as a permanent magnet is a magnetic dipole.

To check the value of the permanent electric field it is generally easier to check the surface potential of the sample. Indeed, using the triode Corona system (tip 6/grid 8/electrode 4—see FIG. 2), the surface potential of sample 2 (Vₛ) takes the value of the potential imposed on the grid (V_{g}) and thus:

$$E = \frac{{V}_{s}}{d} = \frac{{V}_{g}}{d}$$

where d is the thickness of the sample and E the electric field.

The quantity of charges which are present in the material of the sample depends on the thickness of this material (d), its dielectric constant (ε) and the capacity of the material preferentially to retain the charges at its surface, deep within it or, in the case of multi-layer systems, at the interfaces.

It is thus estimated that if a material retains its charges (Q) at its surface (S), the surface charge density (σ) is then equal to:

$$σ = \frac{Q}{S} = \frac{{ɛɛ}_{0} {V}_{s}}{d} ( {ɛ}_{o} \text{:} vacuum permittivity ) .$$

In the case of deep storage, it is more difficult to determine the volume charge density (ρ) in the material.

A typical order of magnitude is a charge of 2 mC/m², which corresponds to a surface potential of 200 V for 500 nm of SiO₂.

The charging can be accomplished under standard temperature and pressure conditions (20° C. at 10⁵ Pa); however, there is no requirement that it is not accomplished under other conditions, and notably at higher temperatures or lower pressures, and vice versa. Nor is it required that the sample is not heated when it is being charged; the effect of this is generally to increase the depth of penetration of the charges in the material and stability.

Charging is generally accomplished in ambient air (0₂: 20%, N₂: 80%). However, there is no requirement that these ratios are not changed, or that the gases are not changed.

The tip voltage (Vₚ) is of the order of magnitude of a few kilovolts. The voltage of the grid (V_{g}) can vary between 0 V and 500 V. The two values can be positive (Corona+) or negative (Corona−). These voltages can, for example, be obtained using DC/HV converters.

The space between the tip and the grid, and the space between the grid and the sample, is generally of the order of 1 cm. For their part, the holes of the grid are roughly 1 mm in size.

Another technique can be used for charging, namely the wet electrode method (also called the liquid electrode method) instead of Corona discharge.

On the subject of this method, reference may be made to the article by K. Ikezaki et al., Thermally Stimulated Currents from Ion-Injected Teflon-FEP Film Electrets, Jpn. J. Appl. Phys. 20 (1981) pp. 1741-1747.

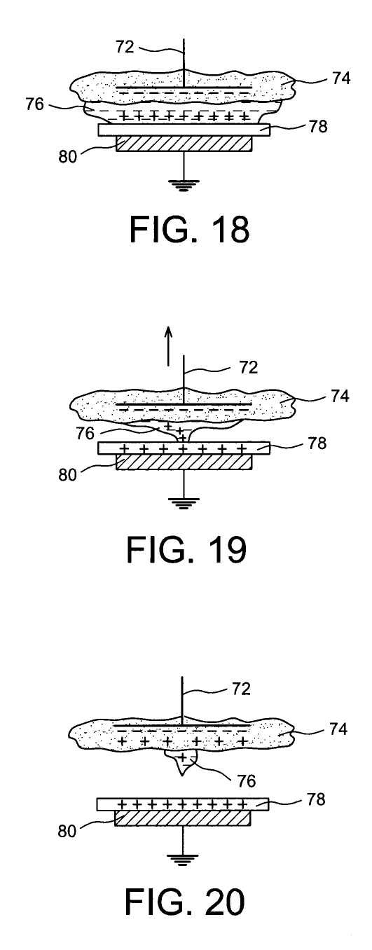

The principle of this method is illustrated schematically by FIGS. 18, 19 and 20.

In these figures, reference 72 designates an upper electrode made of platinum, reference 74 a cotton pad, reference 76 an aqueous solution of electrolytes, reference 78 a layer constituting a sample, and reference 80 a lower electrode supporting the sample and which is grounded.

The upper electrode is charged negatively (by appropriate means, which are not represented) and surrounded by pad 74. And the upper electrode is located on the sample.

In a first step (FIG. 18), the upper electrode is brought close to the solution. The latter and the sample are then charged positively by influence.

In a second step (FIG. 19), the solution is absorbed by the pad and the positive charges remain on the sample. The upper electrode fitted with the pad soaked with the solution is then moved away.

When the upper electrode has been retracted there is then a positively charged sample on electrode 80 (FIG. 20).

We now return to the Smart Cut™ method.

In order to produce a thin layer of monocrystalline material, it is possible advantageously to use two types of existing techniques for transferring thin layers, enabling the monocrystalline character to be preserved: Smart Cut™ technology, based on implantation of gaseous ions (typically hydrogen ions), and the technique of bonding/thinning.

These techniques are unique techniques which enable a monocrystalline layer to be transferred to a host substrate. These techniques are perfectly controlled on silicon, and among other things allow the industrial manufacture of SOI (Silicon On Insulator) wafers.

These two techniques are differentiated by the range of thicknesses of material which it is sought to transfer; the Smart Cut™ method enables very small thicknesses to be attained, typically of less than approximately 0.5 μm.

The Smart Cut™ method (see the article by M. Bruel, Silicon on insulator material technology, Electronic letters, 31 (14), p. 1201-1202, 1995), allows SOI substrates to be produced, including silicon on an insulator.

Smart Cut™ technology can be summarised schematically by the following four essential steps:

Step 1: Implantation of hydrogen is accomplished on a substrate A of oxidised Si. The oxide layer then constitutes the future buried insulator film of the SOI structure. This step of implantation causes formation of a zone which is embrittled throughout, which consists of microcavities, the growth of which is the basis for the separation phenomenon.

Step 2: Bonding by molecular adhesion enables implanted plate A to be attached to supporting plate (backplate or base) B, which is not necessarily oxidised. A surface preparation is required in order to obtain a high-quality bonding.

Step 3: The fracture step is undertaken at the embrittled zone by means of a heat treatment in the range of 400° C.-600° C. This produces firstly the SOI structure, and also the initially implanted substrate A, peeled from the transferred layer. The substrate can then be recycled in order to accomplish another transfer.

Step 4: End treatments consist, firstly, of a high-temperature annealing to consolidate the bonding interface between the transferred thin film and the supporting substrate and, secondly, of a polishing which enables the desired end thickness of the surface silicon film to be obtained, and also a satisfactory surface condition.

The thickness of the transferred layer is related directly to the implantation energy of the ion beam, and thus enables satisfactory flexibility to be obtained in terms of the combinations of thicknesses (thin film and buried oxide). As an example, the transferred silicon thickness can range from a few tens of nanometres to approximately 2 μm by using a traditional implanter (energy less than 210 keV).

The transferred layers are uniform and homogenous throughout since they are defined by an implantation depth, and not by a mechanical thinning.

The manufacturing costs are reduced, firstly through recycling of the substrates (the initially implanted plates can be reused after transferring the thin film) and secondly through the use of standard microelectronics facilities.

It is a flexible method which for example allows heretostructures to be produced. Smart Cut™ technology thus e. g. enables the advantages of a supporting substrate made of bulk Si (notably cost, weight and mechanical characteristics) and of a thin active layer to be combined. It is thus possible to transfer layers of different materials such as:
SiC—see L. DiCioccio et al., “Silicon carbide on insulator formation by Smart Cut™ process”, Master, Sci. Eng. vol. B46, pp. 349-356 (1997);
GaAs—see E. Jalaguier et al., “Transfer on thin GaAs film on silicon substrate by proton implantation process”, Electronic letters, vol. 34, n^{o} 4, pp. 408-409 (1998);
InP—see E. Jalaguier et al., “Transfer of thin InP film onto silicon substrate by proton implantation process”, IEEE Proc. 11th International Conference on Indium Phosphide and Related Materials, Davos (Switzerland) (1999);
GaN—see A. Tauzin et al., “Transfers of 2-inch GaN films onto sapphire substrates using Smart Cut™ technology”, Electronics Letters 2005, vol. 41, N^{o} 11;
or Ga—see C. Deguet et al.—“200 mm Germanium-On-Insulator (GeOI) structures realized from epitaxial Germanium wafers by the Smart Cut™ technology”, Electro Chemical Society 2005.

These transfers can be accomplished on different substrates, notably quartz, Si, Ge, GaAs and sapphire.

We now return to the Bragg mirror.

One solution to isolate the BAW-type (Bulk Acoustic Wave) acoustic resonator from the substrate is based on a principle which is very widely used in optics: the Bragg mirror.

Its acoustic transposition consists in producing a stack under the resonator in which quarter-wave layers of low acoustic impedance materials alternate with quarter-wave layers of high acoustic impedance materials. In this configuration the resonators are also called SMRs (Solidly Mounted Resonators).

This idea, which was proposed in 1965—see the article by W. E. Newell which, like the other documents cited below, is mentioned at the end of the present description—for quartz resonators, was again used in the BAW SMR resonators produced by K. M. Lakin et al. (1995).

In the case of the Bragg mirror the reflection coefficient depends on the materials and of the number of layers used, and is not constant over the entire frequency band. We shall therefore describe the key parameters and characteristics of the response of a Bragg mirror.

It is possible to calculate the reflection coefficient of a Bragg mirror for a longitudinal wave, using a model of the transmission line type—see the article by K. M. Lakin (1991). This model enables the acoustic impedance Zₙ of a layer to be represented as a function of the acoustic impedance of lower layer Zₙ₋₁ by the expression:

$${Z}_{n} = {Z}_{mat} \cdot ( \frac{{Z}_{n - 1} \cdot cos ( {θ}_{mat} ) + i \cdot {Z}_{mat} \cdot sin ( {θ}_{mat} )}{{Z}_{mat} \cdot cos ( {θ}_{mat} ) + i \cdot {Z}_{n - 1} \cdot sin ( {θ}_{mat} )} ) ,$$

where

$${θ}_{mat} = \frac{ω \cdot {e}_{mat}}{{V}_{mat}}$$

is the pulsation and Zₘₐₜ, eₘₐₜ and Vₘₐₜ are respectively the acoustic impedance, the thickness and the speed of the longitudinal wave of the layer.

Using this expression it is possible to determine the impedance Z_{Bragg} of the Bragg mirror at the interface between the lower electrode and the Bragg mirror. Reflection coefficient R for the longitudinal wave is written as follows:

$$R = \frac{{Z}_{elec} - {Z}_{Bragg}}{{Z}_{elec} + {Z}_{Bragg}} ,$$

where Z_{elec} represents the acoustic impedance of the lower electrode.

The reflection coefficient of the Bragg mirror is a function of the number of layers. The pair of materials SiO₂/W is commonly used since, using four or more layers, it enables the acoustic insulation function to be satisfied.

The number of layers required increases when materials with a lower acoustic impedances ratio are used. Thus, in the case of the SiO₂/AlN pair, which was one of the first to be used, two layers are required to attain sufficient reflection—see the article by M. A. Dubois.

The acoustic impedances ratio also defines the reflection bandwidth of the Bragg mirror. The higher the acoustic impedances ratio, the wider the range of frequencies for which the Bragg mirror has satisfactory reflection. Thus, this reflection range for a mirror with six layers reaches 1.5 GHz for the SiO₂/AlN pair and 2.8 GHz for the SiO₂/W pair.

The SiO₂/W pair therefore has the advantage that it uses few layers and has a very broad range of reflection. Conversely, its integration in BAW filters requires that the tungsten is etched outside the active zones in order to prevent parasitic capacitive couplings.

The articles mentioned above are as follows:

W. E. Newell, Face-mounted piezoelectric resonators, Proc. of IEEE, pp. 575-581, 1965,

K. M. Lakin et al., Development of miniature filters for wireless applications, IEEE Trans. Microwave Theory. Tech., vol. 43, n^{o} 12, pp. 2933-2939, 1995

K. M. Lakin, Fundamental properties of thin film resonators, IEEE Freq. Contr. Symp., pp. 201-206, 1991

M. A. Dubois, Aluminium nitride and lead zirconate-titanate thin films for ultrasonics applications: integration, properties and devices, Thesis of EPFL, 1999.

1. An electromechanical device, comprising:
a dielectric stack having two opposite faces, and comprising an electret layer; and
two electrodes supported respectively by the two opposite faces of the dielectric stack,
wherein the electret layer is a mineral electret layer.

2. The electromechanical device of claim 1, wherein the electret layer has permanent electric charges forming an electromechanical coupling.

3. The electromechanical device of claim 1, wherein the dielectric stack is situated outside the electret layer and is non-piezoelectric.

4. The electromechanical device of claim 1, wherein a thickness of the electret layer is from 3 nanometres to 30 micrometres.

5. The electromechanical device of claim 1, further comprising a substrate on one face of which the dielectric stack and the two electrodes are located.

6. The electromechanical device of claim 5, wherein the substrate comprises a cavity, or hole, which emerges at least in the face of the substrate on which one of the two electrodes lies, such that said electrode is at least partly above the cavity.

7. The electromechanical device of claim 5, further comprising an acoustic Bragg grating comprising two opposite faces, one of which is lying on one face of the substrate, and the other of which supports one of the two electrodes.

8. The electromechanical device of claim 1, wherein the electret layer is crystalline.

9. The electromechanical device of claim 1, wherein the electret layer is amorphous.

10. A method for manufacturing an electromechanical device, the method comprising:
forming a dielectric stack comprising a layer comprising a dielectric material;
permanently electrically charging the layer to form an electret layer; and
forming a first and a second electrode respectively on two opposite faces,
wherein the dielectric material is a mineral dielectric material.

11. The method of claim 10, wherein a thickness of the electret layer is from 3 nanometres to 30 micrometres.

12. The method of claim 10, wherein the dielectric stack and the first and second electrode are formed above a substrate.

13. The method of claim 12, comprising,
forming, from the substrate, the dielectric stack comprising the layer on the first electrode;
permanently electrically charging the layer;
forming the second electrode on the dielectric stack; and
eliminating a sacrificial layer, at least partly, to form a hole or cavity under the first electrode,
wherein the substrate comprises the sacrificial layer and the first electrode is situated above the sacrificial layer.

14. The method of claim 12, comprising:
forming, at one face of the substrate, an etch-stop layer, then forming the first electrode, which lies on said face of the substrate, above the etch-stop layer;
forming the dielectric stack on the first electrode;
permanently electrically charging the layer comprising a dielectric material;
forming the second electrode on the dielectric stack; and
etching the substrate from a face opposite the one face as far as the etch-stop layer, to form a hole or cavity, under the first electrode.

15. The method of claim 12, comprising:
forming an acoustic Bragg grating on the substrate, at one face of the substrate; then
forming the first electrode and the dielectric stack on the Bragg grating;
permanently electrically charging the layer comprising dielectric material; and
forming the second electrode on the dielectric stack.

16. The method of claim 10, wherein permanent electrical charging occurs by a method selected from the group consisting of ion implantation, electronic implantation, Corona discharge, and a wet electrode method.

17. The electromechanical device of claim 1, wherein a thickness of the electret layer is less than or equal to approximately 1 μm.

18. The method of claim 10, wherein a thickness of the electret layer is less than or equal to approximately 1 μm.
